(19) United States
(12) Patent Application Publication
(10) Pub. No.: US 2013/0264485 A1
(43) Pub. Date: Oct. 10, 2013

(54) METHOD OF MANUFACTURING RADIATION DETECTION APPARATUS, RADIATION DETECTION APPARATUS, AND RADIATION IMAGING SYSTEM

(71) Applicant: CANON KABUSHIKI KAISHA, Tokyo (JP)

(72) Inventors: Jun Kawanabe, Kodama-gun (JP); Chiori Mochizuki, Sagamihara-shi (JP); Minoru Watanabe, Honjo-shi (JP); Keigo Yokoyama, Honjo-shi (JP); Masato Ofuji, Honjo-shi (JP); Kentaro Fujiyoshi, Tokyo (JP); Hiroshi Wayama, Saitama-shi (JP)

(21) Appl. No.: 13/853,780

(22) Filed: Mar. 29, 2013

(30) Foreign Application Priority Data
Apr. 4, 2012 (JP) 2012-085500

(51) Int. Cl. H01L 31/0224; G01T 1/24; H01L 31/18

(52) U.S. Cl. CPC H01L 31/0224; H01L 31/18; G01T 1/24
USPC 250/369; 257/431; 438/73

(57) ABSTRACT

A method of manufacturing a radiation detection apparatus including a photoelectric conversion element that includes a first electrode placed above a substrate, a semiconductor layer placed on the first electrode, and a second electrode placed on the semiconductor layer includes forming the second electrode by removing a portion of an electrode layer formed over the semiconductor layer, the portion being located on an end section of the semiconductor layer. The method includes forming an insulating layer such that the insulating layer covers a portion of the semiconductor layer that is not covered by the second electrode. The method further includes forming a third electrode on at least one portion of the insulating layer such that the insulating layer is interposed between the third electrode and the end section of the semiconductor layer.

### BACKGROUND OF THE INVENTION

1. Field of the Invention

The present disclosure relates to a radiation detection apparatus applied to medical diagnostic imaging systems, non-destructive testing systems, analyzers using radiation, and the like and also relates to a radiation imaging system.

2. Description of the Related Art

In recent years, techniques for manufacturing liquid crystal panels including thin-film transistors (TFTs) have advanced and screens have been getting larger with the increase in size of panels. The techniques are applied to large-surface area sensors (detection devices) including conversion elements such as semiconductor photoelectric conversion elements and switch elements (also referred to as switching elements) such as TFTs. Such area sensors are used in combination with phosphors wavelength-converting radiations such as X-rays into light such as visible light in the field of radiation detection apparatus such as medical X-ray detection devices.

Japanese Patent Laid-Open No. 2007-59887 discloses a photoelectric transducer including a TFT, a photoelectric conversion element, and an insulating layer interposed therebetween. The photoelectric conversion element includes an upper electrode having an end section placed inside a semiconductor layer and impurity-doped semiconductor layer which are components of the photoelectric conversion element. That is, an electrode region is placed inside a peripheral section of a semiconductor layer region when the semiconductor layer, which is a component of the photoelectric conversion element, is viewed from above. Japanese Patent Laid-Open No. 5-145110 discloses a configuration in which an end section of a semiconductor layer is covered by a passivation layer and an upper electrode (transparent electrode) is placed over the passivation layer.

However, in the photoelectric transducer disclosed in Japanese Patent Laid-Open No. 2007-59887, an electric field is unlikely to be applied to an end section of the semiconductor layer because the upper electrode of the photoelectric conversion element is placed inside the semiconductor layer of the photoelectric conversion element. This reduces the efficiency of collecting carriers present in the end section of the semiconductor layer in some cases. Therefore, a reduction in signal output rate occurs to cause an afterimage or crosstalk. This may result in a reduction in image quality.

In the configuration disclosed in Japanese Patent Laid-Open No. 5-145110, since the upper electrode covers the whole semiconductor layer including an end section (peripheral section), an electric field is applied to the end section of the semiconductor layer and therefore the efficiency of collecting carriers can be increased to a certain extent.

The configuration disclosed in Japanese Patent Laid-Open No. 5-145110 is obtained in such a way that the passivation layer is formed on the semiconductor layer, a region of the passivation layer that is outside the end section of the semiconductor layer is removed by patterning, and the upper electrode is then formed. Since a material for forming the passivation layer, as well as the semiconductor layer, is a silicon-based material, a surface of the semiconductor layer is damaged to a certain extent during the patterning (etching) of the passivation layer. When the semiconductor layer surface has damage, structural defects of the damaged portion (region) are increased and may possibly trap carries generated in the semiconductor layer.

In the configuration disclosed in Japanese Patent Laid-Open No. 5-145110, the surface defects of the semiconductor layer are increased as described above. Therefore, it is difficult to obtain an element which includes a semiconductor layer having few surface defects and which has high carrier-collecting efficiency.

The upper electrode disclosed in Japanese Patent Laid-Open No. 5-145110 is not electrically separated for each pixel. Therefore, arbitrary potentials cannot be separately applied to the upper electrode and the end section of the semiconductor layer.

### SUMMARY OF THE INVENTION

The inventors have made intensive investigation to solve the above problems, thereby completing inventive concepts presented herein. The present disclosure provides a method of manufacturing a radiation detection apparatus including a photoelectric conversion element including a first electrode placed above a substrate, a semiconductor layer placed on the first electrode, and a second electrode placed on the semiconductor layer. The method includes forming the second electrode by removing a portion of an electrode layer formed over the semiconductor layer, the portion being located on an end section of the semiconductor layer; forming an insulating layer such that the insulating layer covers a portion of the semiconductor layer that is not covered by the second electrode; and forming a third electrode on at least one portion of the insulating layer such that the insulating layer is interposed between the third electrode and the end section of the semiconductor layer.

Furthermore, the present disclosure provides a radiation detection apparatus including a photoelectric conversion element including a first electrode placed above a substrate, a semiconductor layer placed on the first electrode, and a second electrode which is placed on the semiconductor layer so as not to cover an end section of the semiconductor layer; an insulating layer covering the end section of the semiconductor layer; and a third electrode which is placed on the insulating layer such that the insulating layer is interposed between the third electrode and the end section of the semiconductor layer and which is made from an electrode layer different from the second electrode.

According to the present disclosure, unlike a technique disclosed in Japanese Patent Laid-Open No. 5-145110, an electrode can be formed above a region of a semiconductor layer with an insulating layer interposed therebetween without damaging a surface of the semiconductor layer, the semiconductor layer being a component of a photoelectric conversion element, the region being not covered by an upper electrode of the photoelectric conversion element, the electrode being different from the upper electrode. As a result, the semiconductor layer, which is a component of the photoelectric conversion element, has little damage and an electric field can be applied to the region not covered by the upper electrode of the photoelectric conversion element from the electrode different from the upper electrode through the insulating layer, which overlies the upper electrode. Therefore, the efficiency of collecting carriers generated in an end section of the semiconductor layer is increased. Unlike Japanese Patent Laid-Open No. 2007-59887, no reduction in signal readout rate occurs. Therefore, the following device can be provided: an imaging device which can reduce problems such as afterimages and crosstalk and which has high image quality.

Further features of the present invention will become apparent from the following description of exemplary embodiments with reference to the attached drawings.

### BRIEF DESCRIPTION OF THE DRAWINGS

FIG. 1A is a schematic plan view of pixels arranged in two rows and two columns used in a first embodiment of the present disclosure.

FIG. 1B is a sectional view taken along the line A-A of FIG. 1A.

FIGS. 2A, 2C, and 2E are illustrations showing the mask patterns of photomasks used in steps performed in the first embodiment.

FIGS. 2B, 2D, and 2F are sectional views, taken along the line A-A of FIG. 1A, illustrating steps performed in the first embodiment.

FIG. 3A is a schematic plan view of pixels arranged in two rows and two columns used in a second embodiment.

FIG. 3B is a sectional view taken along the line B-B of FIG. 3A.

FIG. 3C is a sectional view taken along the line IIIC-IIIC of FIG. 3A.

FIGS. 4A, 4C, and 4E are illustrations showing the mask patterns of photomasks used in steps performed in the second embodiment.

FIGS. 4B, 4D, and 4F are sectional views, taken along the line B-B of FIG. 3A, illustrating steps performed in the second embodiment.

FIG. 5A is a schematic plan view of pixels arranged in two rows and two columns used in a third embodiment.

FIG. 5B is a sectional view taken along the line C-C of FIG. 5A.

FIGS. 6A and 6C are illustrations showing the mask patterns of photomasks used in steps performed in the third embodiment.

FIGS. 6B and 6D are sectional views, taken along the line C-C of FIG. 5A, illustrating steps performed in the third embodiment.

FIG. 7A is a schematic plan view of pixels arranged in two rows and two columns used in a fourth embodiment.

FIG. 7B is a sectional view taken along the line D-D of FIG. 7A.

FIGS. 8A, 8C, 8E, 8G, 81, and 8K are illustrations showing the mask patterns of photomasks used in steps performed in the fourth embodiment.

FIGS. 8B, 8D, 8F, 8H, 8J, and 8L are sectional views, taken along the line D-D of FIG. 7A, illustrating steps performed in the fourth embodiment.

FIG. 9 is an illustration showing the configuration of a radiation imaging system according to a fifth embodiment.

FIG. 10A is an illustration showing an end section (upper surface) of a semiconductor layer.

FIG. 10B is an illustration showing an end section (side surface) of a semiconductor layer.

FIGS. 11A to 11F are illustrations showing examples of the arrangement of third electrodes.

### DESCRIPTION OF THE EMBODIMENTS

Embodiments of the present disclosure will now be described with reference to the accompanying drawings. The present invention is not limited to the embodiments discussed herein. The term “radiation” as used herein includes beams, such as α-rays, β-rays, and γ-rays, generated by particles (including photons) emitted by radioactive decay; beams, such as X-rays, particle rays, and cosmic rays, having similar or higher energy; and the like.

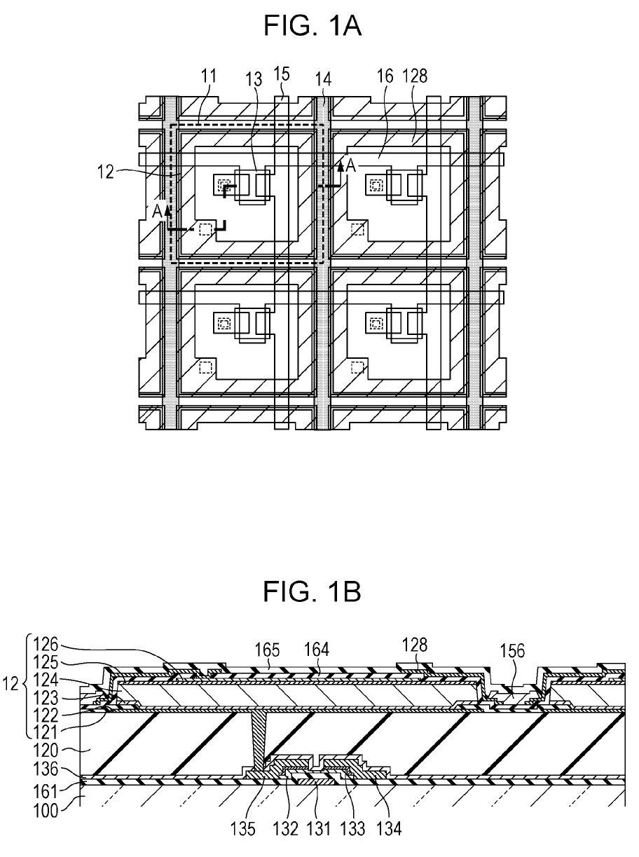

The term “photoelectric conversion element” as used herein refers to a semiconductor element including a first electrode 122, semiconductor layers 123 to 125, and a second electrode 126. A photoelectric conversion element used herein is one converting light or radiation into an electrical signal. The photoelectric conversion element can be used in direct conversion-type radiation detection apparatus directly converting radiation into an electrical signal and indirect conversion-type radiation detection apparatus converting radiation into visible light with a wavelength converter such as a scintillator and then converting the visible light into an electrical signal. A first electrode and second electrode used herein are provided with a number for convenience of description and either one may be an upper or lower electrode. A semiconductor layer used herein may be of a predetermined conductivity type (p-type, i-type, or n-type) and may have a single or multilayer structure. Furthermore, an insulating layer may be provided between the semiconductor layer and an electrode as required. The photoelectric conversion element may typically be of a pin type (nip type) or a MIS type (refer to FIG. 1).

As used herein, the expression “an end section of an upper electrode of a photoelectric conversion element is placed inside a semiconductor layer” means that when the photoelectric conversion element is viewed from above (the upper side), a region of the upper electrode is contained in a semiconductor region and the upper electrode is placed inside a peripheral section of the semiconductor layer.

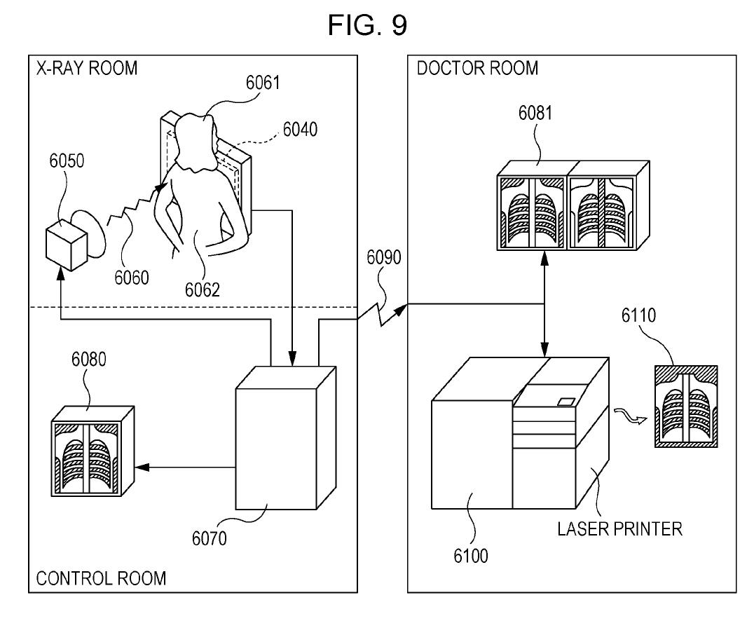

The term “an end section of a semiconductor layer” as used herein refers to at least one portion of a peripheral region of a semiconductor layer. The term “peripheral region” covers a peripheral section of the upper surface of the semiconductor layer and side surfaces (also referred to as side walls) of the semiconductor layer. FIGS. 10A and 10B illustrate an end section of a semiconductor layer used in the present disclosure. FIG. 10A is a top view of the semiconductor layer. FIG. 10B is a sectional view of the semiconductor layer. With reference to FIG. 10A, reference numeral 1001 represents the outside edge of the semiconductor layer (semiconductor region), reference numeral 1002 represents a peripheral section (hatched section) of the upper surface of the semiconductor layer, and reference numeral 1003 represents the boundary between the peripheral section of the upper surface of the semiconductor layer and a section other than the peripheral section (typically the boundary between the peripheral section and the upper electrode). That is, a region interposed between the outside edge of the semiconductor layer and the above boundary corresponds to the end section (peripheral section) of the semiconductor layer when the semiconductor layer is viewed from above. The distance (width) between the outside edge of the semiconductor layer and the above boundary can be arbitrarily designed depending on how to apply an electric field. With reference to FIG. 10B, reference numeral 1004 represents the upper surface of the semiconductor layer, reference numeral 1005 represents side surfaces (side walls) of the semiconductor layer, and reference numeral 1006 represents the lower surface of the semiconductor layer. Both the peripheral section 1002 of the upper surface of the semiconductor layer and the side surfaces (side walls) 1005 of the semiconductor layer are included in the end section of the semiconductor layer.

As used herein, the expression “an electrode (third electrode 128) is placed so as to cover at least one region of an end section of a semiconductor layer of a photoelectric conversion element with an insulating layer interposed therebetween” means that an insulating layer is placed on at least one portion of an end section (a peripheral section of the upper surface of a semiconductor layer or a side surface of the semiconductor layer) of the semiconductor layer and the electrode is placed on at least one portion of the insulating layer. The electrode can be arbitrarily designed such that the electrode is placed to so as to cover the end section of the semiconductor layer, is placed only on the peripheral section of the upper surface of the semiconductor layer or a side surface of the semiconductor layer, or is placed near (spaced from) the end section of the semiconductor layer with a predetermined distance therebetween (refer to FIG. 1). The term “electrically separated” as used herein means that electrodes intended to be separated are direct-currently (DC) separated from each other. The term “direct-currently (DC) separated” as used herein means that electrodes intended to be separated are insulated from each other with a resistor or space such that a current substantially affecting the function of a device (for example, a radiation detection apparatus) including the electrodes does not flow between the electrodes and different potentials can be applied to the electrodes.

### First Embodiment

The configuration of one of pixels used in a radiation detection apparatus according to a first embodiment is described with reference to FIGS. 1A and 1B. A photoelectric conversion element used in this embodiment has a pin structure. The photoelectric conversion element is not limited to the pin structure and may have a MIS structure (metal-insulator-semiconductor structure.

FIG. 1A is a schematic plan view of pixels arranged in two rows and two columns used in this embodiment. FIG. 1B is a sectional view taken along the line A-A of FIG. 1A.

The radiation detection apparatus includes a pixel 11 that includes a photoelectric conversion element 12 converting radiation or light into a charge and a thin-film transistor (TFT) 13 which outputs an electrical signal corresponding to the charge of the photoelectric conversion element 12 and which is a switch element (also referred to as a switching element). The pixels each include such a switch element and a photoelectric conversion element and are two-dimensionally arranged on a substrate 100. The photoelectric conversion element 12 is a pin-type photodiode and includes a first electrode (lower electrode) 122; a pin-type semiconductor layer including a third semiconductor sub-layer (n-type sub-layer) 123, a fourth semiconductor sub-layer (i-type sub-layer) 124, and a fifth semiconductor sub-layer (p-type sub-layer) 125; and a second electrode (upper electrode) 126. The photoelectric conversion element 12 and the TFT 13 are arranged on the substrate 100 with a first interlayer insulating layer 120 interposed therebetween. The substrate 100 is a glass substrate, a substrate which is coated with an insulating material and which has an insulating surface, or the like. In description below, the side of a surface of the substrate 100 that is overlaid with the photoelectric conversion element 12 and the TFT 13 is referred to as “upper side”, a surface facing that surface is referred to as “lower side”, and a direction parallel to these surfaces is referred to as “lateral direction”.

The TFT 13 includes a control electrode (gate electrode) 131 placed on the substrate 100, a first insulating layer 161, a first semiconductor layer 132, a second semiconductor layer 133, a first main electrode 134, a second main electrode 135, and a second insulating layer 162. The second semiconductor layer 133 has an impurity concentration higher than that of the first semiconductor layer 132. The first semiconductor layer 132 has a region in contact with a portion of the second semiconductor layer 133 that is in contact with the first main electrode 134, a region in contact with a portion of the second semiconductor layer 133 that is in contact with the second main electrode 135, and a region which is located between these regions and which functions as a channel region for the TFT 13. The control electrode 131 is electrically connected to a control line 16. The first main electrode 134 is electrically connected to a signal line 15. The second main electrode 135 is electrically connected to the first electrode 122 of the photoelectric conversion element 12.

The photoelectric conversion element 12 is placed on the first interlayer insulating layer 120. The photoelectric conversion element 12 includes the first electrode 122; the pin-type semiconductor layer, which includes the third semiconductor sub-layer 123, the fourth semiconductor sub-layer 124, and the fifth semiconductor sub-layer 125; the second electrode 126; a fourth insulating layer 164; and a third electrode 128, these components being arranged from the lower side (the first interlayer insulating layer 120 side) in that order. The third semiconductor sub-layer 123 has an impurity concentration higher than that of the fourth semiconductor sub-layer 124. Likewise, the fifth semiconductor sub-layer 125 has an impurity concentration higher than that of the fourth semiconductor sub-layer 124 and is doped with an impurity different in conductivity type from an impurity contained in the third semiconductor sub-layer 123.

A photodiode may be configured to be of a pin-type or a nip-type from the upper side. The third electrode 128 is electrically connected to the second electrode 126 through a contact hole formed in the fourth insulating layer 164.

The first interlayer insulating layer 120 is preferably an organic or inorganic insulating layer. The use of an insulating layer with a low dielectric constant allows capacitances generated between the photoelectric conversion element 12, the TFT 13, the control line 16, and the signal line 15 to be low. The increase in total capacitance of the signal line 15 or the control line 16 increases noise in an acquired image or causes a need to increase the time constant during the transfer of a signal from the TFT 13. As a result, it is difficult to read an image at high speed. Therefore, an insulating layer capable of having a low dielectric constant and a large thickness is preferably placed between the TFT 13 and the photoelectric conversion element 12. In the case of using an organic insulating layer, a material, such as an acrylic resin or polyimide, having a low dielectric constant is generally used. In the case of forming the semiconductor layer, which is a component of the photoelectric conversion element 12, by a plasma-enhanced chemical vapor deposition (PECVD) process, the semiconductor layer is preferably at a temperature not higher than the upper temperature limit of the organic insulating layer. In general, a reduction in temperature during film formation causes many defects in a film, resulting in that a film with relatively higher resistance is formed as compared with those formed at elevated temperature.

The second electrode 126 is placed inside the fifth semiconductor sub-layer 125. As used herein, the expression “placed inside a semiconductor layer” means that when a photoelectric conversion element is viewed from above, an electrode region is located in a semiconductor region and the outside edge of the electrode region is less than the outside edge of the semiconductor region. The reason for using such a configuration is as described below.

The influence of misalignment during the patterning of the second electrode 126 or the influence of recession during the etching of the photoelectric conversion element 12 may possibly create such a structure (also referred to as an overhang) that an end section (outside end) of the second electrode 126 extends outside the fourth semiconductor sub-layer 124 of the photoelectric conversion element 12. Such a structure reduces the coverage of a protective layer for the photoelectric conversion element 12 to cause a reduction in reliability. Therefore, the second electrode 126 is placed inside the fourth semiconductor sub-layer 124 of the photoelectric conversion element 12.

In particular, in the case of using the organic insulating layer, the fourth semiconductor sub-layer 124 of the photoelectric conversion element 12 needs to be formed at a temperature not higher than the upper temperature limit of the organic insulating layer and therefore may possibly have high resistance as described above. In order to ensure reliability, the second electrode 126 needs to be placed inside the fourth semiconductor sub-layer 124. Therefore, an electric field is not sufficiently applied to carriers generated in a region of an end section of the fourth semiconductor sub-layer 124 of the photoelectric conversion element 12, the region being not covered by the second electrode 126; hence, the efficiency of collecting carriers may possibly be reduced.

Therefore, the third electrode 128 is placed above the second electrode 126 with the fourth insulating layer 164 interposed therebetween so as to cover at least one portion of the region of the end section of the fourth semiconductor sub-layer 124 of the photoelectric conversion element 12, the region being not covered by the second electrode 126. This allows an electric field to be applied to the end section of the fourth semiconductor sub-layer 124 to increase the efficiency of collecting the carriers generated in the uncovered region of the end section of the fourth semiconductor sub-layer 124 of the photoelectric conversion element 12.

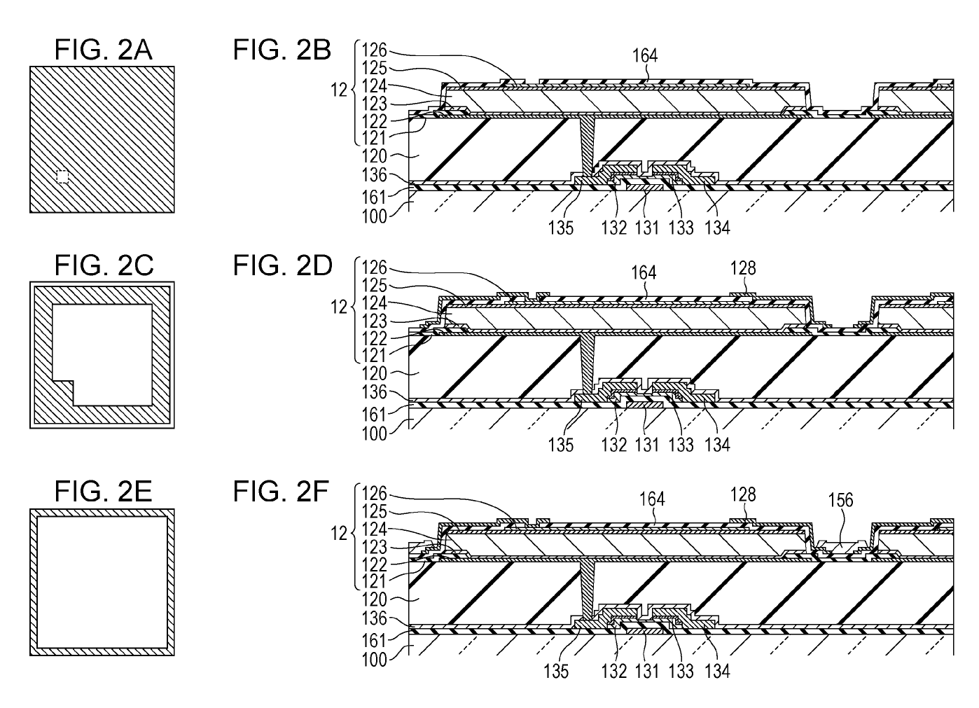

A method of manufacturing the radiation detection apparatus according to the first embodiment of the present disclosure is described below with reference to FIGS. 2A to 2F. Steps subsequent to the formation of the first interlayer insulating layer 120 are described in detail using sectional views in process. FIGS. 2A, 2C, and 2E are illustrations showing the mask patterns of photomasks used in the above steps. FIGS. 2B, 2D, and 2F are sectional views, taken along the line A-A of FIG. 1A, illustrating the above steps. The TFT 13 and the photoelectric conversion element 12 can be formed by a known process. An example of the process is described using a first step to ninth step below.

In the first step, a conductive film, such as an Al film, used to form the control electrode 131 is formed over the substrate 100 having an insulating surface by a sputtering process. The conductive film is partly etched, whereby the control electrode 131 of the TFT 13 is formed (patterning).

In the second step, an insulating film, such as a silicon nitride film, used to form the first insulating layer 161 is formed over the substrate 100 having the control electrode 131. Furthermore, the following films are formed: a semiconductor film, such as an amorphous silicon film, corresponding to the first semiconductor layer 132 and an impurity-doped semiconductor film, such as an amorphous silicon film doped with a tetravalent element such as phosphorus, used to form the second semiconductor layer 133. The first insulating layer 161, the first semiconductor layer 132, and the second semiconductor layer 133 are formed by a PECVD process. The amorphous silicon film doped with the tetravalent element, such as phosphorus, is used herein to form the second semiconductor layer 133. The present invention is not limited to this film. An amorphous silicon film doped with a trivalent element such as boron may be used herein. Each formed semiconductor film is etched, whereby the first semiconductor layer 132 and the second semiconductor layer 133, which are components of the TFT 13, are formed (patterning).

In the third step, a conductive film, such as an Al film, used to form the first main electrode 134 and second main electrode 135 of the TFT 13 is formed over the substrate 100 having the first semiconductor layer 132 and the second semiconductor layer 133 by a sputtering process. This conductive film is partly etched using a predetermined mask, whereby the first main electrode 134 and second main electrode 135 of the TFT 13 are formed (patterning). The semiconductor films are partly etched using a mask similar to the mask used to form the first main electrode 134 and the second main electrode 135, thereby removing a portion of the impurity-doped semiconductor film that is located on the semiconductor film used to form the channel region of the TFT 13.

In the fourth step, an insulating film (the second insulating layer 162) such as a silicon nitride film is formed over the substrate 100 having the first main electrode 134 and the second main electrode 135 by a PECVD process. A contact hole is formed in a portion of this insulating film that is electrically connected to the photoelectric conversion element 12, which is a photodiode placed on the second main electrode 135. Through the above steps, a TFT section is completed.

In the fifth step, the first interlayer insulating layer 120 is formed over the substrate 100 having the TFT section using a photosensitive acrylic resin and a coater such as a spinner. A polyimide resin or the like can be used as such a photosensitive organic resin. Thereafter, a contact hole is formed in the first interlayer insulating layer 120 by photolithography including exposure and development.

In the sixth step, ITO, which is used to form a third electrode layer 153, is deposited over the substrate 100 having the first interlayer insulating layer 120 by a sputtering process. An ITO film is formed (patterning) by wet etching, whereby the first electrode 122, which is an individual electrode for a photodiode, is formed. The ITO film, which is amorphous, is crystallized by annealing, whereby the first electrode 122 is reduced in resistance. In this embodiment, ITO is used to form the first electrode 122. Materials other than ITO can be used herein. For example, the following materials can be used: transparent conductive oxides such as InZnO, InGaO, ZnO, SnO₂, and InGaZnO; conductive organic materials such as polyethylene dioxythiophene (PEDOT) and polystyrene sulfonate (PSS); and lightproof conductive materials such as Al.

In the seventh step, an insulating film (third insulating layer 163), such as a silicon nitride film, used to form an inter-electrode inorganic insulating layer 121 is formed over the substrate 100 having the first electrode 122 by a PECVD process. The inter-electrode inorganic insulating layer 121 is formed (patterning) between the pixels by partly etching this insulating layer, whereby a third insulating layer 163 is formed. In this embodiment, a configuration including the inter-electrode inorganic insulating layer 121 is used. The inter-electrode inorganic insulating layer 121 is one formed as required and is not necessarily needed. The effect of using the inter-electrode inorganic insulating layer 121 is that the inter-electrode inorganic insulating layer 121 (third insulating layer 163) functions as an etching stopper in a dry etching step of a pixel separation process. This prevents the first interlayer insulating layer 120 from being exposed to species for dry etching, enables shape stable processing, and allows the pollution of semiconductor surfaces by the first interlayer insulating layer 120 to be reduced.

In the eighth step, an amorphous silicon film, doped with a tetravalent element such as phosphorus, used to form the third semiconductor sub-layer 123 is formed over the substrate 100 having the inter-electrode inorganic insulating layer 121. Furthermore, the following films are formed: a semiconductor film, such as an amorphous silicon film, used to form the fourth semiconductor sub-layer 124 and an amorphous silicon film, doped with a trivalent element such as boron, used to form the fifth semiconductor sub-layer 125. These semiconductor films are formed by a PECVD process in that order. The temperature at which these semiconductor films are formed is preferably not higher than the upper temperature limit of the first interlayer insulating layer 120 and is, for example, about 230° C. to 280° C. The following laminate is used herein: a laminate formed by depositing the amorphous silicon film (n-type sub-layer) doped with the tetravalent element, the semiconductor film (i-type sub-layer) not doped with any impurity, and the amorphous silicon film (p-type sub-layer) doped with the trivalent element in that order from the lower side. The present invention is not limited to the laminate. The following laminate may be used herein: a laminate formed by depositing an amorphous silicon film (p-type sub-layer) doped with a trivalent element, an amorphous silicon film (i-type sub-layer) not doped with any impurity, and an amorphous silicon film (n-type sub-layer) doped with a tetravalent element in that order. The term “amorphous silicon film (i-type sub-layer) not doped with any impurity” as used herein is an expression of convenience and includes an amorphous silicon film containing no impurity at all, an amorphous silicon film substantially not doped with any impurity, and a slightly doped (lightly doped) amorphous silicon film.

The ninth step and subsequent steps below are characteristic of the method of manufacturing the radiation detection apparatus.

In the ninth step, an ITO film which is an electrode layer is formed over the substrate 100 having the amorphous silicon multilayer film by a sputtering process. The ITO film is then partly removed by wet etching using a predetermined mask, whereby the second electrode 126 of the photoelectric conversion element 12 is formed (patterning). The third semiconductor sub-layer 123, the fourth semiconductor sub-layer 124, and the fifth semiconductor sub-layer 125 are dry-etched using the same mask as that used form the second electrode 126 of the photoelectric conversion element 12, whereby photodiodes are separated for each pixel. In this operation, the third semiconductor sub-layer 123, fourth semiconductor sub-layer 124, and fifth semiconductor sub-layer 125 of the photoelectric conversion element 12 are located inside the first electrode 122 and may be located outside the first electrode 122. The effect of the presence of the third semiconductor sub-layer 123, the fourth semiconductor sub-layer 124, and the fifth semiconductor sub-layer 125 inside the first electrode 122 is that an electric field can be applied to carriers generated in the end section of the fourth semiconductor sub-layer 124 of the photoelectric conversion element 12 and therefore the efficiency of collecting carriers is increased. The reason why the second electrode 126 is placed inside the fifth semiconductor sub-layer 125 as described above is as described below. The influence of misalignment during the patterning of the second electrode 126 or the influence of recession (overhang) during the etching of the photoelectric conversion element 12 may possibly create such a structure that an end section of the second electrode 126 extends outside the fourth semiconductor sub-layer 124 of the photoelectric conversion element 12. This reduces the coverage of a protective layer for the photoelectric conversion element 12 to cause a reduction in reliability. Therefore, design or manufacturing margins can be ensured by placing the second electrode 126 inside the fourth semiconductor sub-layer 124 of the photoelectric conversion element 12.

Subsequent steps are further described in detail using sectional views in process and mask illustrations.

In a tenth step shown in FIG. 2B, an insulating film, such as a silicon nitride film, used to form the fourth insulating layer 164 is formed over the substrate 100 having the photoelectric conversion element 12 by a PECVD process. This insulating layer is selectively etched using a tenth photomask shown in FIG. 2A, whereby a contact hole is formed therein. The contact hole is provided at a position where the second electrode 126 is located. The second electrode 126 functions as a protective layer for the fifth semiconductor sub-layer 125. This prevents the fifth semiconductor sub-layer 125 from being damaged by etching during the formation of this contact hole, allows the junction of the fifth semiconductor sub-layer 125 and the second electrode 126 to be good, and reduces dark current and noise.

In this embodiment, the second electrode 126 and the third electrode 128 are connected to each other through the contact hole formed in the tenth step and are supplied with potential from a common bias line 14 below. The second electrode 126 and the third electrode 128 may be supplied with potential from another line. In this case, no contact hole needs to be formed in the tenth step. In this case, the fifth semiconductor sub-layer 125 of the photoelectric conversion element 12 can be formed so as to have no or little etching damage and therefore a similar effect can be achieved.

In an 11th step shown in FIG. 2D, an ITO film is formed over the substrate 100 having the fourth insulating layer 164 by a sputtering process. This ITO film is wet-etched using an 11th photomask shown in FIG. 2C, whereby the third electrode 128 is formed (patterning). In this step, the third electrode 128 is placed so as to cover at least one region of an end section of the semiconductor layer of the photoelectric conversion element 12 with the fourth insulating layer 164 interposed therebetween. This allows an electric field to be applied to a region of the semiconductor layer of the photoelectric conversion element 12 to increase the efficiency of collecting carriers, the region being not covered by the second electrode 126. In this configuration, the third electrode 128 is separated between the pixels and need not be separated.

A region for forming the third electrode 128 need not necessarily be formed over the end section of the semiconductor layer of the photoelectric conversion element 12. The region for forming the third electrode 128 may be formed only on a peripheral section of the upper surface of the semiconductor layer or a side surface thereof, may be formed near the end section of the semiconductor layer with a predetermined distance therebetween, or may be arbitrarily designed. The degree of design freedom can be increased and the efficiency of collecting carriers can be controlled by varying the region for forming the third electrode 128. For example, the efficiency of collecting carriers can be distributed in the whole element to a certain extent by varying a pixel region or the region for forming the third electrode 128 for each pixel.

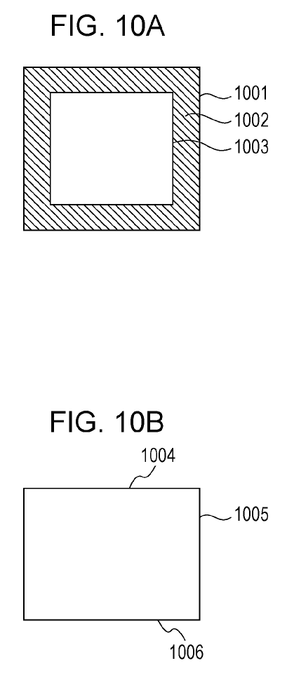

FIGS. 11A to 11F are illustrations showing examples of the arrangement of third electrodes used in the present disclosure. Reference numeral 1101 represents the third electrodes and reference numeral 1102 represents a region of a semiconductor layer. An insulating layer is placed (interposed) between the semiconductor layer and the third electrodes.

FIG. 11A shows a configuration in which a third electrode covers the whole of a peripheral section of the upper surface of a semiconductor layer. FIGS. 11B to 11F each show a configuration in which a third electrode is placed on at least one of side and corner portions of a region of a semiconductor layer. The third electrodes can be optimally designed in consideration of the efficiency of collecting carriers (how to apply an electric field to a semiconductor layer), manufacturing cost, or the like.

In this embodiment, ITO is used to form the second electrode 126 and the third electrode 128. The following materials can be used: transparent electrode materials; transparent conductive oxides such as InZnO, InGaO, ZnO, SnO₂, and InGaZnO; and conductive organic materials such as polyethylene dioxythiophene (PEDOT) and polystyrene sulfonate (PSS).

In a 12th step shown in FIG. 2F, a conductive film, such as an Al film, used to form the bias line 14 is formed over the substrate 100 having the third electrode 128 by a sputtering process. This conductive film is etched using a 12th photomask shown in FIG. 2E, whereby the bias line 14 is formed (patterning). In this operation, the third electrode 128 and the bias line 14 are electrically connected to each other between the pixels. In this embodiment, the bias line 14 is placed directly on the third electrode 128. A second interlayer insulating layer 140 may be placed between the third electrode 128 and the bias line 14 in such a manner that the second interlayer insulating layer 140 is planarized and the bias line 14 is placed thereon.

Finally, in a 13th step, a protective layer is formed over the substrate 100 having the bias line 14, whereby a configuration shown in FIG. 1B is obtained.

### Second Embodiment

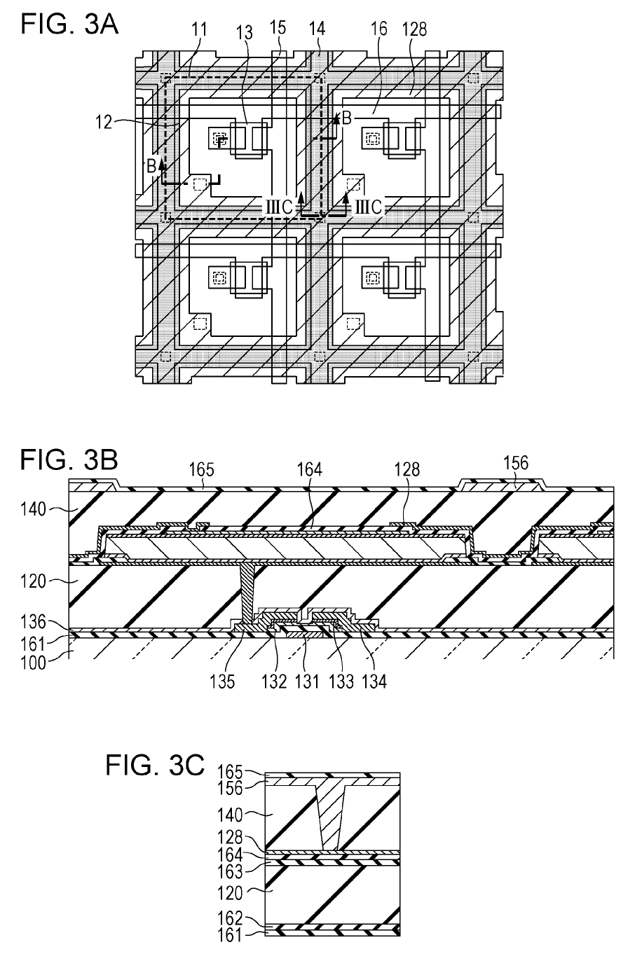

A second embodiment of the present disclosure is described below with reference to FIGS. 3A, 3B, and 3C. FIG. 3A is a schematic plan view of pixels arranged in two rows and two columns used in the second embodiment. FIG. 3B is a sectional view taken along the line B-B of FIG. 3A. FIG. 3C is a sectional view taken along the line IIIC-IIIC of FIG. 3A. The same components as those described in the first embodiment are denoted by the same reference numerals as those used in the first embodiment.

This embodiment differs from the first embodiment in that the third electrode 128 used in the first embodiment is separated between the pixels but a third electrode 128 used in this embodiment is not separated between pixels. In addition, in this embodiment, a bias line 14 is placed above a second interlayer insulating layer 140 placed on the third electrode 128 and is connected to the third electrode 128 between the pixels through a contact hole formed in the second interlayer insulating layer 140. Furthermore, the bias line 14 is laid out in a grid pattern. In this configuration, an end section of a semiconductor layer of a photoelectric conversion element 12 has a region which is not covered by a second electrode but is covered by the third electrode 128 with a fourth insulating layer 164 interposed therebetween; hence, an electric field is applied to the end section of the semiconductor layer, the efficiency of collecting carriers is increased, no reduction in signal output occurs, and a device with high image quality can be provided.

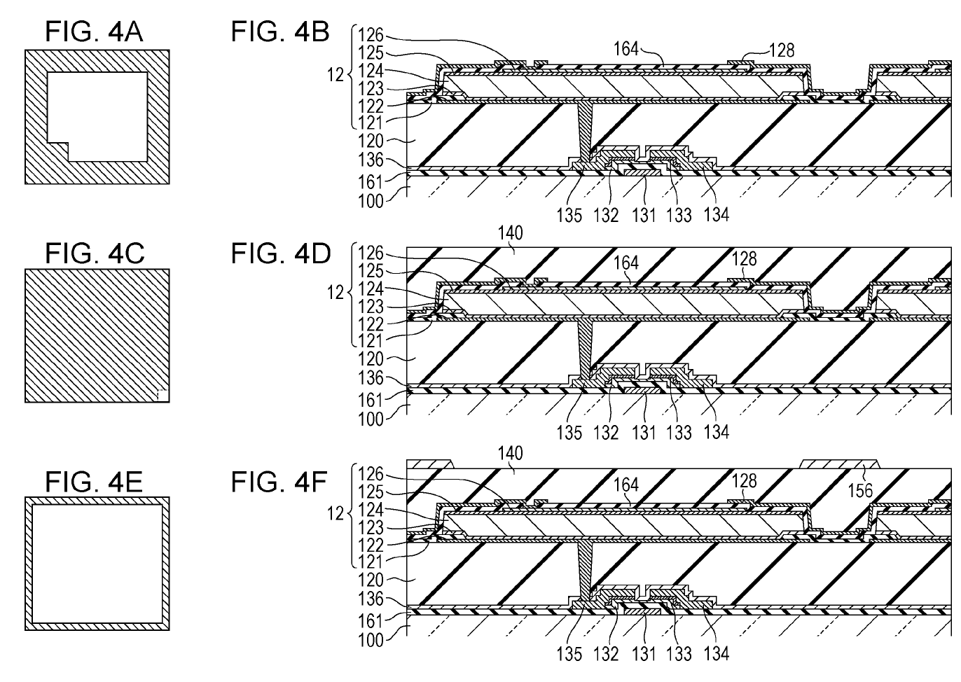

A method of manufacturing a radiation detection apparatus according to the second embodiment is described below with reference to FIGS. 4A to 4F. Steps subsequent to the formation of the second interlayer insulating layer 140 are described in detail using sectional views in process. FIGS. 4A, 4C, and 4E are illustrations showing the mask patterns of photomasks used in the above steps. FIGS. 4B, 4D, and 4F are sectional views, taken along the line B-B of FIG. 3A, illustrating the above steps. A first step to tenth step are the same as those described in the first embodiment.

In an 11th step shown in FIG. 4B, an ITO film is formed over a substrate 100 having a layered configuration, formed by the tenth step, by a sputtering process. The ITO film is selectively wet-etched using an 11th mask shown in FIG. 4A, whereby the third electrode 128 is formed (patterning). The third electrode 128 extends to an adjacent pixel.

In a 12th step shown in FIG. 4D, the second interlayer insulating layer 140 is formed over the substrate 100 using a photosensitive acrylic resin and a coater such as a spinner. A polyimide resin or the like can be used as such a photosensitive organic resin. Thereafter, a contact hole is formed in the second interlayer insulating layer 140 by exposure and development using a 12th photomask shown in FIG. 4C.

In a 13th step shown in FIG. 4F, a conductive film, such as an Al film, used to form a third electrode layer 156 is formed over the substrate 100 by a sputtering process. The conductive film is etched using a 13th photomask shown in FIG. 4E, whereby the third electrode layer 156 is formed.

Finally, in a 14th step, a protective layer is formed over the substrate 100 having the third electrode layer 156, whereby a configuration shown in FIG. 3B is obtained.

### Third Embodiment

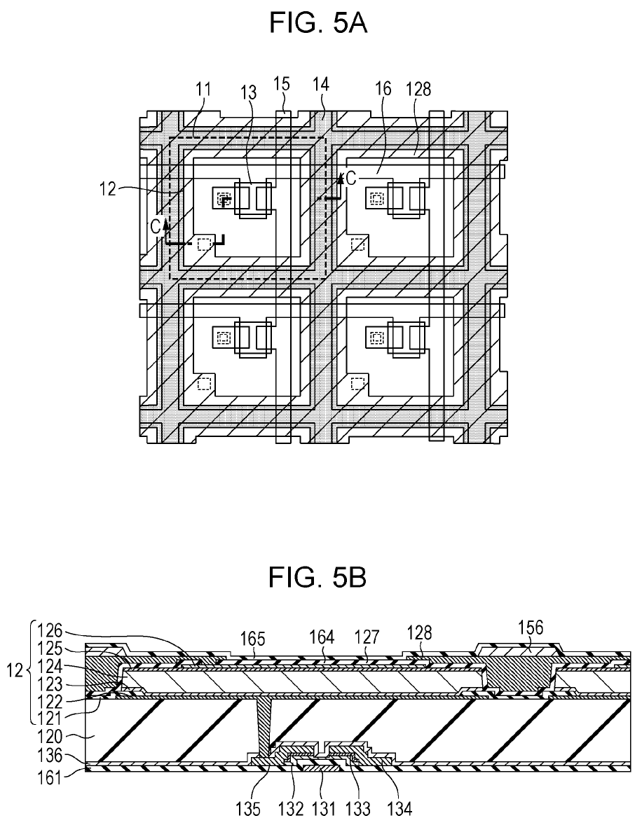

A third embodiment of the present disclosure is described below with reference to FIGS. 5A and 5B. FIG. 5A is a schematic plan view of pixels arranged in two rows and two columns used in the third embodiment. FIG. 5B is a sectional view taken along the line C-C of FIG. 5A. The same components as those described in the first embodiment are denoted by the same reference numerals as those used in the first embodiment. A photoelectric conversion element 12 used in this embodiment has a pin structure and may have a MIS structure.

This embodiment differs from the first embodiment in that an organic conductive film is used to form a third electrode 128. The organic conductive film is formed by a coating process such as a spin casting process using PEDOT or PSS and therefore can be planarized. This allows a bias line 14 to be provided above the planarized third electrode 128 with no interlayer insulating layer therebetween. In this configuration, an end section of a fourth semiconductor sub-layer 124 of a photoelectric conversion element 12 is covered by the third electrode 128 with a fourth insulating layer 164 interposed therebetween; hence, an electric field acts on a region of the end section of the fourth semiconductor sub-layer 124 to increase the efficiency of collecting carriers.

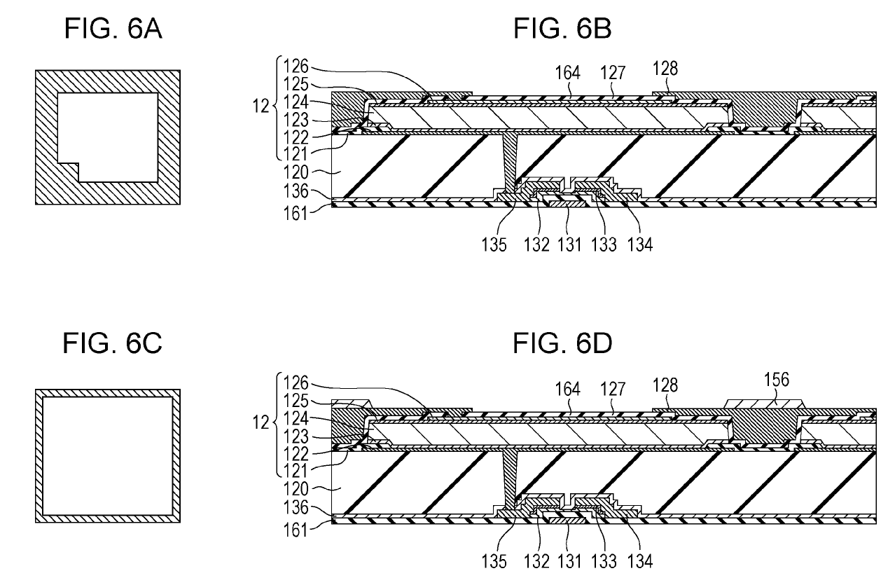

A method of manufacturing a radiation detection apparatus according to the third embodiment is described below with reference to FIGS. 6A to 6D. Steps subsequent to the formation of an interlayer insulating layer are described in detail using sectional views in process. FIGS. 6A and 6C are illustrations showing the mask patterns of photomasks used in the above steps. FIGS. 6B and 6D are sectional views, taken along the line C-C of FIG. 5A, illustrating the above steps. A first step to tenth step are the same as those described in the first embodiment.

In an 11th step shown in FIG. 6B, a conductive organic film, such as a PEDOT or PSS film, used to form the third electrode 128 is formed over a substrate 100 having a layered configuration, formed by the tenth step, by a spin coating process or the like. A polyimide resin can be used to form the conductive organic film. Thereafter, the conductive organic film is etched using an 11th mask shown in FIG. 6A.

In a 12th step shown in FIG. 6D, a conductive film, such as an Al film, used to form a third electrode layer is formed over the substrate 100 having the etched conductive organic film by a sputtering process. The conductive film is etched using a 12th photomask shown in FIG. 6C, whereby the third electrode layer is formed.

Finally, in a 13th step, a silicon nitride film is formed over the substrate 100 having the third electrode layer, whereby a configuration shown in FIG. 5B is obtained.

### Fourth Embodiment

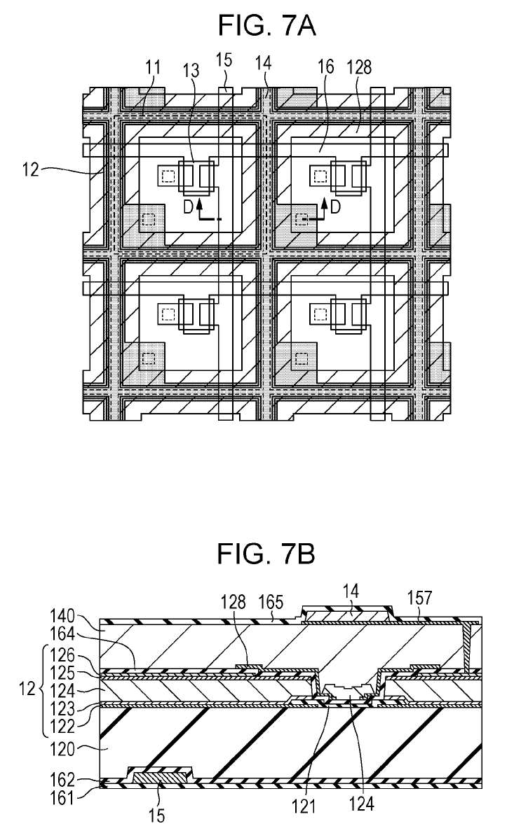

A fourth embodiment of the present disclosure is described below with reference to FIGS. 7A and 7B. FIG. 7A is a schematic plan view of pixels arranged in two rows and two columns used in the fourth embodiment. FIG. 7B is a sectional view taken along the line D-D of FIG. 7A. The same components as those described in the first embodiment are denoted by the same reference numerals as those used in the first embodiment. A photoelectric conversion element 12 used in this embodiment has a pin structure and may have a MIS structure.

This embodiment differs from the first embodiment in that a second electrode 126 and a third electrode 128 are not connected to each other but are electrically separated from each other, the second electrode 126 is connected to a bias line 14 which is placed thereabove with a second interlayer insulating layer 140 interposed therebetween, and the third electrode 128 is connected to a power supply line 17 placed between pixels. In this configuration, a transparent electrode layer 157 made of ITO is placed under the bias line 14. The bias line 14 is made of a low-resistance material such as Al and is lightproof; hence, if the bias line 14 overlaps with the photoelectric conversion element 12 to be connected to the second electrode 126, a loss of aperture ratio is thereby caused. Therefore, the overlap of the bias line 14 with the photoelectric conversion element 12 is avoided and the transparent electrode layer 157 is placed under the bias line 14 and is connected to the second electrode 126. In this embodiment, the transparent electrode layer 157 is placed under the bias line 14. The transparent electrode layer 157 may be placed above the bias line 14. In this embodiment, ITO is used to form the transparent electrode layer 157. The following film may be used to form the transparent electrode layer 157: a conductive organic film made of a transparent electrode material, that is, a transparent conductive material such as InZnO, InGaO, ZnO, SnO₂, or InGaZnO; polyethylene dioxythiophene (PEDOT); or polystyrene sulfonate (PSS). In this embodiment, the transparent electrode layer 157 is not essential. In the case of providing an electrode on a region which needs to transmit light, the electrode may be transparent, may have a small area, or may have an opening such that light passes through the region.

In this configuration, for example, a potential of about −10 V can be applied to the bias line 14, which is connected to the second electrode 126, and a potential of about −15 V can be applied to the power supply line 17, which is connected to the third electrode 128. This configuration allows the potential applied to the second electrode 126 and the potential applied to the third electrode 128 to be independently controlled. The field density of an end section of the photoelectric conversion element 12 is higher as compared to the first to third embodiments. Therefore, a region of an end section of a fourth semiconductor sub-layer 124 has an increased carrier-collecting efficiency, the region being not covered by the second electrode 126. Furthermore, the following advantage is obtained: an advantage that a reduction in signal output rate does not occur or problems such as afterimages and crosstalk do not occur.

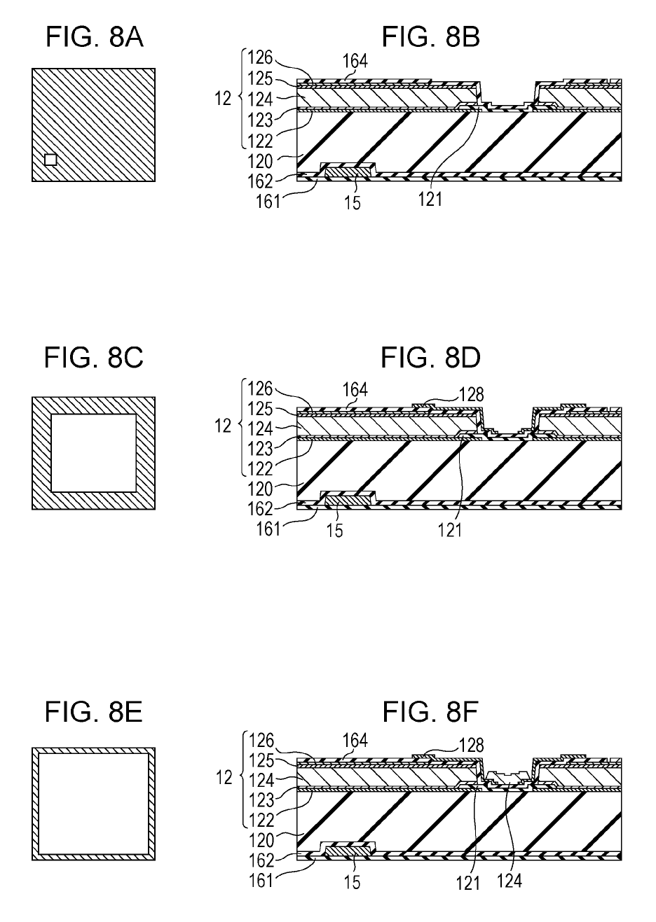

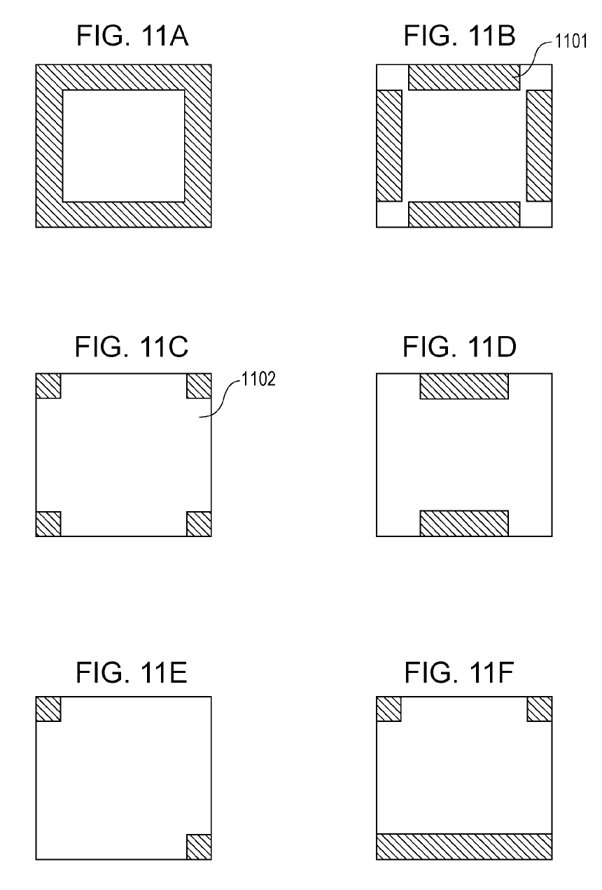

A method of manufacturing a radiation detection apparatus according to the fourth embodiment is described below with reference to FIGS. 8A to 8L. Steps subsequent to the formation of the second interlayer insulating layer 140 are described in detail using sectional views in process. FIGS. 8A, 8C, 8E, 8G, 81, and 8K are illustrations showing the mask patterns of photomasks used in the above steps. FIGS. 8B, 8D, 8F, 8H, 8J, and 8L are sectional views, taken along the line D-D of FIG. 7A, illustrating the above steps. A first step to ninth step are the same as those described in the first embodiment.

In a tenth step shown in FIG. 8B, an insulating film such as a silicon nitride film is formed over a substrate 100 having a layered configuration, formed by the ninth step, by a PECVD process. A portion of the insulating film is selectively etched using a tenth mask shown in FIG. 8A, whereby a fourth insulating layer 164 is formed.

In an 11th step shown in FIG. 8D, an ITO film is formed over the substrate 100 having the fourth insulating layer 164 by a sputtering process. The ITO film is etched using an 11th mask shown in FIG. 8C, whereby the third electrode 128 is formed (patterning).

In a 12th step shown in FIG. 8F, a conductive film such as an Al film is formed over the substrate 100 having the third electrode 128 by a sputtering process. The conductive film is etched using a 12th mask shown in FIG. 8E, whereby the power supply line 17 is formed.

In a 13th step shown in FIG. 8H, the second interlayer insulating layer 140 is formed over the substrate 100 having the power supply line 17 using a photosensitive acrylic resin and a coater such as a spinner. A polyimide resin or the like can be used as such a photosensitive organic resin. Thereafter, a contact hole is formed in the second interlayer insulating layer 140 by exposure and development using a 13th photomask shown in FIG. 8G.

In a 14th step shown in FIG. 8J, an ITO film is formed over the substrate 100 having the second interlayer insulating layer 140 by a sputtering process. The ITO film is wet-etched using a 14th photomask shown in FIG. 8I, whereby the transparent electrode layer 157 is formed.

In a 15th step shown in FIG. 8L, a conductive film, such as an Al film, used to form an eighth electrode layer is formed over the substrate 100 having the transparent electrode layer 157 by a sputtering process. This conductive film is wet-etched using a 15th photomask shown in FIG. 8K, whereby the bias line 14 is formed.

Finally, in a 16th step, an insulating film 165 such as a silicon nitride film is formed over the substrate 100 having the bias line 14 by a PECVD process, whereby a configuration shown in FIG. 7B is obtained.

### Fifth Embodiment

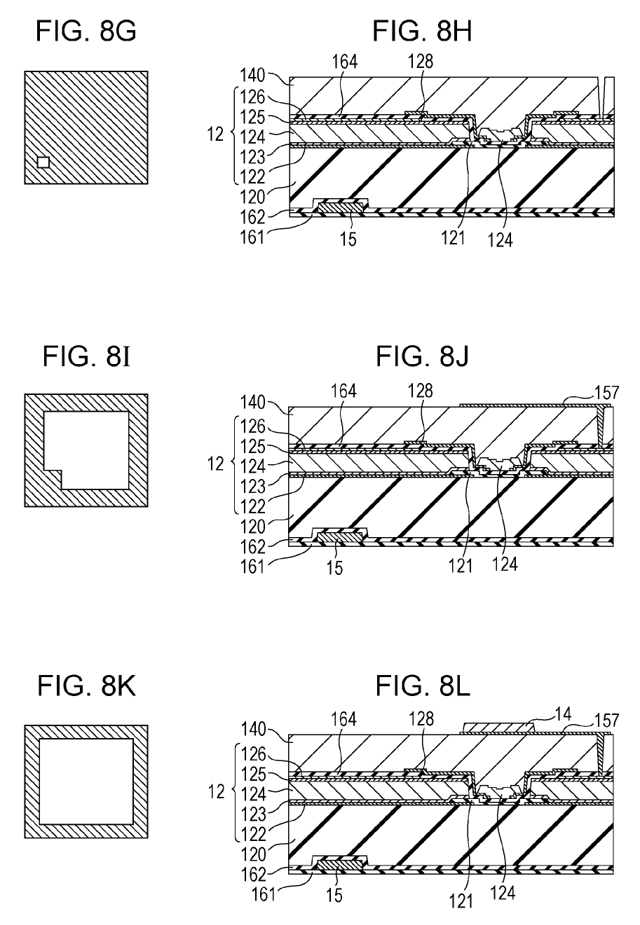

A radiation imaging system (radiation detection system) according to a fifth embodiment of the present disclosure is described below with reference to FIG. 9. The radiation imaging system includes a radiation detection apparatus. FIG. 9 is an illustration showing the configuration of the radiation imaging system.

With reference to FIG. 9, an X-ray 6060 generated from an X-ray tube 6050 which is a radiation source passes through a chest region 6062 of a subject or patient 6061 to enter a radiation detection apparatus 6040 including a scintillator placed above a photoelectric conversion element 12 of a photoelectric conversion section 3. The incident X-ray contains information about the inside of the body of the patient 6061. The scintillator emits light in response to the incident X-ray. The photoelectric conversion section 3 photoelectrically converts the light emitted from the scintillator into electric information. This information is converted into digital information, which is processed into an image by an image processor 6070 serving as a signal-processing unit. The image can be observed with a display 6080, placed in a control room, serving as a display unit.

This information can be transferred to a remote location over a telephone line 6090, provided as required, serving as a transfer unit; can be displayed on a display 6081, placed in a doctor room in another location, serving as a display unit; or can be stored on an optical disk. This information can be used for diagnosis by a doctor in a remote location. Furthermore, this information can be recorded on a film 6110 serving as a recording medium using a film processor 6100 serving as a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-085500 filed Apr. 4, 2012, which is hereby incorporated by reference herein in its entirety.

What is claimed is:

1. A method of manufacturing a radiation detection apparatus including a photoelectric conversion element, the photoelectric conversion element including a first electrode placed above a substrate, a semiconductor layer placed on the first electrode, and a second electrode placed on the semiconductor layer, the method comprising:
forming the second electrode by removing a portion of an electrode layer formed over the semiconductor layer, the portion being located on an end section of the semiconductor layer;
forming an insulating layer such that the insulating layer covers a portion of the semiconductor layer that is not covered by the second electrode; and
forming a third electrode on at least one portion of the insulating layer such that the insulating layer is interposed between the third electrode and the end section of the semiconductor layer.

2. The method according to claim 1, further comprising:
forming a switch element on the substrate;
forming an organic insulating layer over the switch element; and
forming the first electrode on the organic insulating layer such that the first electrode is electrically connected to the switch element.

3. The method according to claim 2, further comprising separating the third electrode for each pixel, wherein the radiation detection apparatus includes the pixels, and the pixels each include the switch element and the photoelectric conversion element and are arranged two-dimensionally.

4. The method according to claim 3, further comprising forming a bias line commonly connected to portions of the third electrode separated for each pixel.

5. A radiation detection apparatus comprising:
a photoelectric conversion element including a first electrode placed above a substrate, a semiconductor layer placed on the first electrode, and a second electrode which is placed on the semiconductor layer so as not to cover an end section of the semiconductor layer;
an insulating layer covering the end section of the semiconductor layer; and
a third electrode placed on the insulating layer such that the insulating layer is interposed between the third electrode and the end section of the semiconductor layer and made from an electrode layer different from the second electrode.

6. The radiation detection apparatus according to claim 5, wherein the third electrode is electrically separated from the second electrode.

7. A radiation imaging system comprising:
the radiation detection apparatus according to claim 5;
a signal-processing unit configured to process a signal transmitted from the radiation detection apparatus; and
a display unit configured to display a signal transmitted from the signal-processing unit.
